(19) United States
(12) Patent Application Publication
(10) Pub. No.: US 2026/0123066 A1
(43) Pub. Date: Apr. 30, 2026

(54) CIS DEVICE AND METHOD FOR FABRICATING SAME

(71) Applicant: WUHAN XINXIN SEMICONDUCTOR MANUFACTURING CO., LTD., Wuhan (CN)

(72) Inventors: Jun ZHOU, Wuhan (CN); Qingwei LUO, Wuhan (CN); Hua HU, Wuhan (CN)

(21) Appl. No.: 19/350,654

(22) Filed: Oct. 6, 2025

(30) Foreign Application Priority Data
Oct. 29, 2024 (CN) 202411525612.2

(51) Int. Cl. H10F 39/18; H10F 39/00

(52) U.S. Cl. CPC H10F 39/1843; H10F 39/014; H10F 39/8053; H10F 39/807; H10F 39/809; H10F 39/811

(57) ABSTRACT

A CMOS image sensor (CIS) device and a method for fabricating the CIS device are disclosed. The CIS device includes a stacked substrate structure including vertically bonded first and second pixel substrates and at least one visible-light pixel unit and at least one infrared light pixel unit that do not laterally overlap. The visible-light pixel unit includes a visible-light sensing element formed in the first pixel substrate, and the infrared light pixel unit includes an infrared light sensing element formed in the second pixel substrate. The visible-light sensing element and the infrared light sensing element are configured to sense visible and infrared light incident on a side of the first pixel substrate away from the second pixel substrate, respectively.

### CROSS-REFERENCE TO RELATED APPLICATION

This application claims the priority of Chinese patent application number 202411525612.2, filed on Oct. 29, 2024, and entitled “CIS DEVICE AND METHOD FOR FABRICATING SAME”, the entire contents of which are incorporated herein by reference.

### TECHNICAL FIELD

The present invention relates to the field of semiconductor technology, and particularly to a CMOS image sensor (CIS) device and a method for fabricating the CIS device.

### BACKGROUND

After years of evolution and improvement, CMOS image sensors (CIS's) are being increasingly regarded as an established technique. Near-infrared (NIR) response is one of the important performance indicators of CIS devices. For example, as automotive CIS chips operate in complex light environments, in addition to demanding requirements of good dynamic range, the ability to detect NIR light is also very important, because this is directly related to the life and property safety of drivers and passengers.

Within currently available silicon-based CIS devices, light of different wavelengths has different absorption depths. In the visible range, red light has the largest absorption depth (approximately 3 μm). Light of longer wavelengths has even larger absorption depths. Consequently, an incident light signal may propagate through a depletion layer in a photodiode without any response. This essentially accounts for lower quantum efficiency (QE) of CIS devices at longer wavelengths in the NIR band.

One known method for increasing response of a CIS device to infrared (IR) radiation is to deepen the pixel photodiodes, thereby enlarging the depth of the depletion layer so that every pixel is able to collect light signals that would otherwise have strayed from the depletion layers. However, this will also increase the likelihood of free charges generated in the pixels being captured by neighboring pixels, i.e., leading to an increased risk of pixel-to-pixel crosstalk. Another method is to reflect incident light signals in pixel structure multiple times, instead of allowing them to travel therein along linear paths as is conventional, to facilitate collection of them by depletion layers. This, however, will greatly increase the actual optical path length, and could not achieve effective collection of infrared light due to its low reflectivity at the interfaces.

### SUMMARY OF THE INVENTION

The present invention provides a CMOS image sensor (CIS) device with enhanced response to infrared light and no risk of increased crosstalk between adjacent pixels, as well as a method for fabricating such a CIS device.

In one aspect, the present invention provides a CMOS image sensor (CIS) device comprising a stacked substrate structure. The stacked substrate structure comprises: a first pixel substrate and a second pixel substrate which are vertically bonded to each other; and at least one visible-light pixel unit and at least one infrared light pixel unit which do not laterally overlap. The visible-light pixel unit comprises a visible-light sensing element formed in the first pixel substrate, and the infrared light pixel unit comprises an infrared light sensing element formed in the second pixel substrate. The visible-light sensing element and the infrared light sensing element are configured to sense visible light and infrared light incident on a side of the first pixel substrate away from the second pixel substrate, respectively.

Optionally, the first pixel substrate may comprise a first substrate and a first dielectric layer formed on a side thereof facing the second pixel substrate, and the second pixel substrate may comprise a second substrate and a second dielectric layer formed on a side thereof facing the first pixel substrate, wherein the second dielectric layer is adjacent to and bonded to the first dielectric layer.

Optionally, a trench isolation structure is formed in the first substrate, and wherein the at least one visible-light pixel unit and the at least one infrared light pixel unit are isolated in the first substrate by the trench isolation structure.

Optionally, a first metal ring is formed in the first dielectric layer, and the infrared light pixel unit is isolated in the first dielectric layer by the first metal ring, and/or wherein a second metal ring is formed in the second dielectric layer, and the infrared light pixel unit is isolated in the second dielectric layer by the second metal ring.

Optionally, when the same infrared light pixel unit is isolated both in the first dielectric layer by the first metal ring and in the second dielectric layer by the second metal ring, the first and second metal rings may be bonded to each other at a bonding interface between the first and second dielectric layers.

Optionally, the first pixel substrate may be a backside-illustrated (BSI) substrate, with the first dielectric layer being formed on a front side of the first substrate, wherein the first pixel substrate further comprises a first metal interconnect structure formed in the first dielectric layer, wherein the second pixel substrate is a front side-illustrated (FSI) substrate, with the second dielectric layer being formed on a front side of the second substrate, wherein the second pixel substrate further comprises a second metal interconnect structure formed in the second dielectric layer, and wherein the first and second metal interconnect structures are bonded to each other at a bonding interface between the first and second dielectric layers.

Optionally, the CIS device may further comprise: a light filter layer formed on the side of the first pixel substrate away from the second pixel substrate; and a lens layer formed on a side of the light filter layer away from the first pixel substrate, wherein the light filter layer comprises a black matrix grid which covers a region between the at least one visible-light pixel unit and the at least one infrared light pixel unit and comprises openings corresponding to the visible-light pixel unit and the infrared light pixel unit, and filter elements filled in the openings, and the lens layer comprises micro-lenses corresponding to the at least one visible-light pixel unit and the at least one infrared light pixel unit.

In another aspect, the present invention provides a method for fabricating a CIS device. The method comprises:
forming a first pixel substrate and a second pixel substrate, the first pixel substrate comprising at least one visible-light pixel region and at least one first infrared light pixel region which do not laterally overlap, the visible-light pixel region provided with a visible-light sensing element, the second pixel substrate comprising at least one second infrared light pixel region that does not laterally overlap, and wherein the second infrared light pixel region is provided with an infrared light sensing element; and
vertically stacking and bonding the first and second pixel substrates together to form a stacked substrate structure, wherein each of the at least one first infrared light pixel region in the first pixel substrate is vertically aligned with a corresponding one of the at least one second infrared light pixel region in the second pixel substrate, wherein the stacked substrate structure comprises a visible-light pixel unit corresponding to the visible-light pixel region and an infrared light pixel unit corresponding to the first infrared light pixel region, the visible-light sensing element and the infrared light sensing element configured to sense visible light and infrared light incident on a side of the first pixel substrate away from the second pixel substrate.

Optionally, forming the first pixel substrate may comprise:
forming a STI structure at a front side of a first substrate to define the at least one visible-light pixel region and the at least one first infrared light pixel region;
forming a visible-light sensing element in the at least one visible-light pixel region; and
forming, on the front side of the first substrate, a first pixel circuit element coupled to the visible-light sensing element, a first dielectric layer covering the first pixel circuit element and a first metal interconnect structure formed in the first dielectric layer and connected to the first pixel circuit element.

Optionally, during the formation of the first dielectric layer and the first metal interconnect structure, a first metal ring may also be formed in the first dielectric layer, an orthographic projection of which on the front side of the first substrate surrounds the first infrared light pixel region.

Optionally, forming the second pixel substrate may comprise:
forming a STI structure at a front side of a second substrate to define the at least one second infrared light pixel region;
forming an infrared light sensing element in the at least one second infrared light pixel region; and
forming, on the front side of the second substrate, a second pixel circuit element coupled to the infrared light sensing element, a second dielectric layer covering the second pixel circuit element and a second metal interconnect structure formed in the second dielectric layer and connected to the second pixel circuit element, and
wherein the first and second dielectric layers are bonded by bonding the first and second pixel substrates, the first and second metal interconnect structures are bonded together at a bonding interface between the first and second dielectric layers.

Optionally, during the formation of the second dielectric layer and the second metal interconnect structure, a second metal ring may also be formed in the second dielectric layer, an orthographic projection of which on the front side of the second substrate surrounds the second infrared light pixel region.

Optionally, the method may further comprise, after the first and second pixel substrates are bonded together:
thinning the first substrate from a backside thereof and forming a DTI structure between the at least one visible-light pixel unit and the at least one infrared light pixel unit;
and sequentially forming a light filter layer and a lens layer on the backside of the first substrate.

The present invention provides a CIS device and a method for fabricating the device, in which at least one visible-light pixel unit and at least one infrared light pixel unit do not laterally overlap. The visible-light pixel unit includes a visible-light sensing element formed in the first pixel substrate, and the infrared light pixel unit includes an infrared light sensing element formed in the second pixel substrate. The visible-light sensing element and the infrared light sensing element are configured to sense visible and infrared light incident on a side of the first pixel substrate away from the second pixel substrate, respectively. Compared to the visible-light pixel unit, the incident light corresponding to the infrared light pixel unit travels a longer distance before it is detected, resulting in enhanced response to the infrared radiation. Additionally, incident light corresponding to the visible-light pixel unit travels a shorter distance before it is detected due to a shallower depletion layer, reducing the risk of crosstalk between adjacent pixel units

### BRIEF DESCRIPTION OF THE DRAWINGS

FIG. 1 shows a schematic flowchart of a method for fabricating a CIS device according to an embodiment of the present invention.

FIGS. 2A and 2B show schematic cross-sectional views of first and second substrates after STI structures are formed at front sides thereof in a method for fabricating a CIS device according to an embodiment of the present invention.

FIGS. 3A and 3B show schematic cross-sectional views of first and second substrates after visible-light and infrared light sensing elements are formed therein, respectively, in a method for fabricating a CIS device according to an embodiment of the present invention.

FIGS. 4A and 4B show schematic cross-sectional views of first and second substrates after pixel circuit elements are formed at surfaces thereof in a method for fabricating a CIS device according to an embodiment of the present invention.

FIGS. 5A and 5B show schematic cross-sectional views of first and second substrates after first and second dielectric layers are formed thereon respectively, in a method for fabricating a CIS device according to an embodiment of the present invention.

FIG. 6 shows a schematic cross-sectional view of first and second pixel substrates after they are bonded to each other in a method for fabricating a CIS device according to an embodiment of the present invention.

FIG. 7 shows a schematic cross-sectional view of a structure resulting from forming DTI structures, a light filter layer and a lens layer on a side of a first pixel substrate away from a second pixel substrate in a method for fabricating a CIS device according to an embodiment of the present invention.

### DETAILED DESCRIPTION

CMOS image sensor (CIS) devices and methods for fabricating the same according to specific embodiments of the present invention will be described in greater detail below with reference to the accompanying drawings. From the following description, advantages and features of the present invention will become more apparent. Note that the figures are provided in a very simplified form not necessarily drawn to exact scale for the only purpose of helping to explain the embodiments disclosed herein in a more convenient and clearer way. Also note that the order of steps in the method as presented herein is not the only order in which these steps must be performed. Rather, some of the steps may be omitted, and/or other steps that are not described herein may be added. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

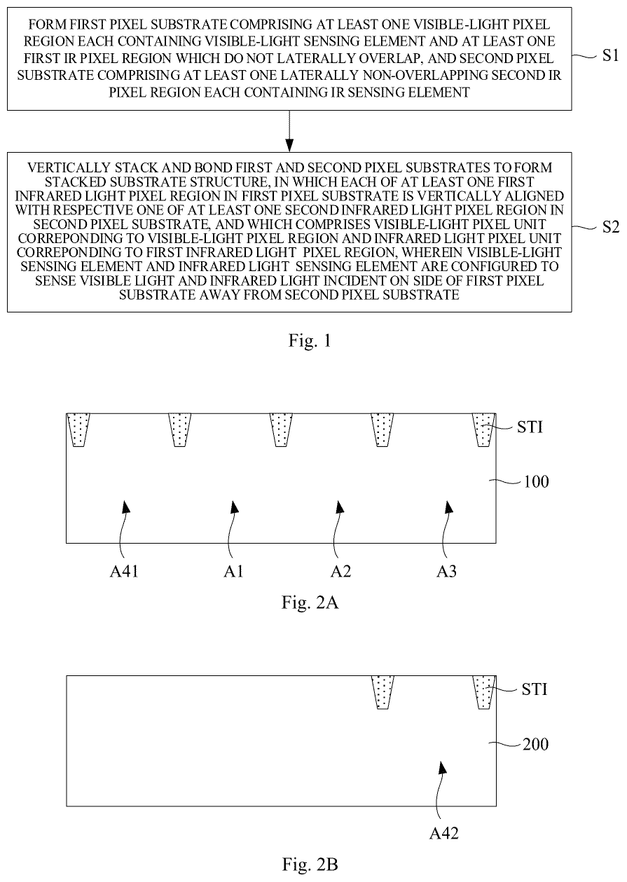

Referring to FIG. 1, a method for fabricating a CMOS image sensor (CIS) device according to an embodiment of the present invention includes:
in step S1, forming a first pixel substrate and a second pixel substrate, the first pixel substrate comprising at least one visible-light pixel region and at least one first infrared light pixel region which do not laterally overlap, the visible-light pixel region provided with a visible-light sensing element, the second pixel substrate comprising at least one laterally non-overlapping second infrared light pixel region that is provided with an infrared light sensing element; and
in step S2, vertically stacking and bonding the first and second pixel substrates together to form a stacked substrate structure, in which the at least one first infrared light pixel region in the first pixel substrate is vertically aligned with a corresponding one of the at least one second infrared light pixel region in the second pixel substrate, the stacked substrate structure comprising a visible-light pixel unit corresponding to the visible-light pixel region and an infrared light pixel unit corresponding to the first infrared light pixel region, the visible-light sensing element and the infrared light sensing element respectively configured to sense visible light and infrared light incident on a side of the first pixel substrate away from the second pixel substrate.

In the stacked substrate structure formed according to this method, for a visible-light pixel unit, incident light enters from the side of the first pixel substrate away from the second pixel substrate (i.e., the incident light side) and is sensed by the visible-light sensing element within the first pixel substrate. Moreover, for an infrared light pixel unit, the light incident from the side of the first pixel substrate away from the second pixel substrate travels through the first pixel substrate and dielectrics between the first and second pixel substrates and then enters the second pixel substrate, where it is sensed by the infrared light sensing element. Therefore, the infrared light is detected after it travels a longer distance, compared to visible light. The shorter optical path in the visible-light pixel unit is sufficient for visible light detection, while the longer optical path in the infrared light pixel unit allows infrared light to be detected by a depletion layer in the infrared light sensing element without propagating therethrough. This results in enhanced response to infrared radiation. In addition, a depletion layer in the visible-light pixel unit has a smaller depth, which can reduce the risk of crosstalk. In this method, the visible-light and infrared light pixel units are integrated at a high level by bonding the first and second pixel substrates together, helping miniaturize the CIS device and associated chip. Further, in the stacked substrate structure, the visible-light pixel unit is laterally offset from the infrared light pixel unit, without any overlap therebetween. This allows the visible-light and infrared light pixel units to separately form images without sharing a common optical path, avoiding possible mutual interference between respective optical paths. Furthermore, using the separated infrared light pixel unit for imaging allows for infrared-specific signal collection and processing, resulting in improved infrared light imaging performance and quality. The method is further described below with respect to specific embodiments.

FIGS. 2A and 2B show cross-sectional views of a first substrate 100 and a second substrate 200 after a shallow trench isolation (STI) structure STI is formed at front sides thereof. Referring to FIGS. 1, 2A and 2B, in step S1, a first pixel substrate and a second pixel substrate are formed from the first substrate 100 and the second substrate 200, respectively. The first substrate 100 and the second substrate 200 may each be any of various substrates known in art to be suitable for the fabrication of CIS devices. For example, any of the first substrate 100 and the second substrate 200 may include one of silicon, germanium, silicon germanium, silicon carbide, gallium oxide, gallium arsenide, gallium phosphide, indium phosphide, indium arsenide, indium antimonide, GaAsP, AlInAs, AlGaAs, GaInAs, GaInP and GaInAsP, or a combination thereof. If required, the first substrate 100 and the second substrate 200 may each be doped with appropriate dopant ions at a suitable concentration. Each of the first substrate 100 and the second substrate 200 has a front side and an opposite backside. The front side is the surface where ions may be performed to form optoelectronic elements therein.

Referring to FIGS. 2A and 2B, in one embodiment, in order to define and isolate different pixel units and the like, the shallow trench isolation (STI) structure STI is formed at the front sides of the first substrate 100 and the second substrate 200. The STI structure STI may have a depth, for example, in the range of 1000 Å to 4000 Å. The STI structure STI may define at least one visible-light pixel region (e.g., A1 to A3, as shown in FIG. 2A) and at least one first infrared light pixel region A41 in the first substrate 100. The visible-light pixel region and first infrared light pixel region are arranged in the first substrate 100 without laterally overlapping. For example, the STI structure STI may define a plurality of large pixel areas in the first substrate 100, each including three visible-light pixel regions and one first infrared light pixel region. The three visible-light pixel regions are configured to sense visible light signals in red, green and blue bands. The first infrared light pixel region A41 is configured for transmission of infrared light (including near-infrared (NIR) light).

As shown in FIG. 2B, the STI structure STI formed at the front side of the second substrate 200 may define at least one second infrared light pixel region A42. In order to effectively isolate the second infrared light pixel region(s) A42 from interference of signals present therearound, in an alternative embodiment, the STI structure STI at the front side of the second substrate 200 may be replaced with deep trench isolation (DTI) structure DTI having a greater depth. Both the DTI and STI structures DTI, STI may be formed using conventional processes.

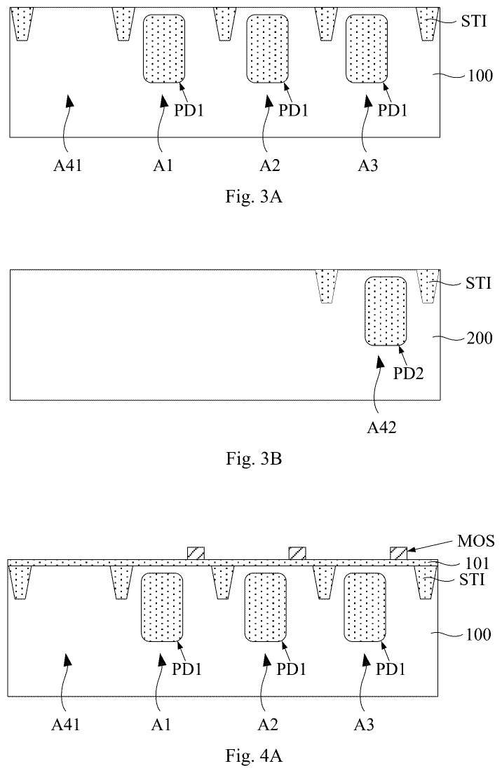

FIG. 3A shows a cross-sectional view of the first substrate 100 after visible-light sensing element(s) PD1 is/are formed therein. Referring to FIG. 3A, after the STI structure STI is formed at the front side of the first substrate 100, one or more ion implantation processes may be performed on the front side of the first substrate 100, forming visible-light sensing element(s) PD1 for sensing visible light in the at least one visible-light pixel region (e.g., A1 to A3) of the first substrate 100. If required, other doped region may also be formed in the first substrate 100 outside the visible-light sensing element(s) PD1. For example, in order to enable transmission of signals sensed by the visible-light sensing element PD1, the first pixel circuit element may be subsequently formed at the front side of the first substrate 100, which is coupled to the visible-light sensing element PD1. The first pixel circuit element may include MOS devices. If required, a well region corresponding to the MOS device may be formed in the first substrate 100 by ion implantation.

FIG. 3B shows a cross-sectional view of the second substrate 200 after infrared light sensing element(s) PD2 is/are formed therein. Referring to FIG. 3B, after the STI structure STI is formed at the front side of the second substrate 200, one or more ion implantation processes may be performed on the front side of the second substrate 200, forming an infrared light sensing element PD2 for sensing infrared light in the at least one second infrared light pixel region A42 of the second substrate 200. If required, other doped region may also be formed in the second substrate 200. For example, in order to enable transmission of signals sensed by the infrared light sensing element PD2, second pixel circuit element may be subsequently formed at the front side of the second substrate 200, which is coupled to the infrared light sensing element PD2. The second pixel circuit element may include MOS device. If required, a well region corresponding to the MOS device may be formed in the second substrate 200 by ion implantation.

The visible-light sensing element PD1 and the infrared light sensing element PD2 may be formed, for example, by doping the respective substrates with dopant ions. Any of the visible-light sensing element PD1 and the infrared light sensing element PD2 may be P-N photodiode, P-N-P photodiode, N-P-N photodiode or other optoelectronic element. In the present embodiment, the visible-light sensing element PD1 and the infrared light sensing element PD2 are, for example, P-N photodiodes.

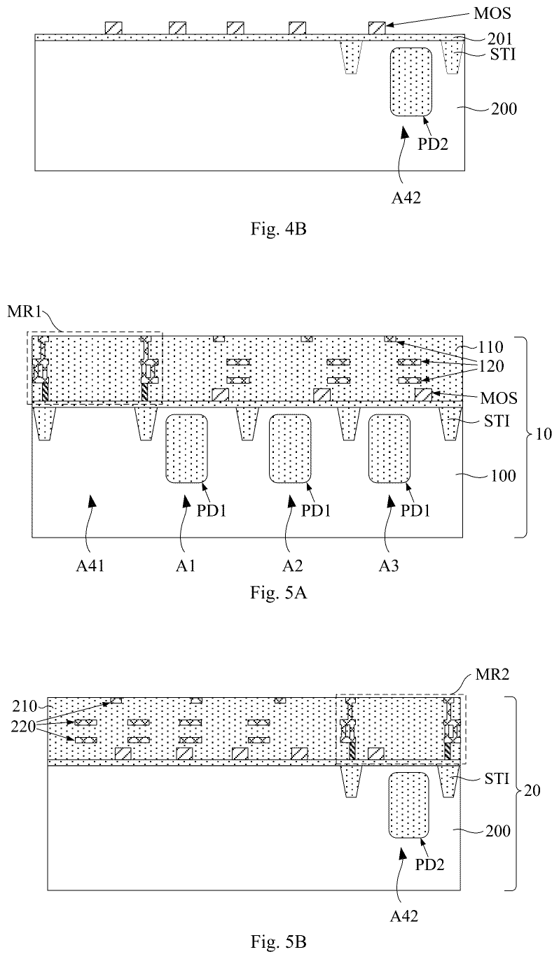

FIG. 4A shows a cross-sectional view of the first substrate 100 after first pixel circuit element is formed on the front side thereof. Referring to FIG. 4A, after the visible-light sensing element(s) PD1 is/are formed in the visible-light pixel region(s) of the first substrate 100, first pixel circuit element may be formed on a surface of the first substrate 100. The structure of the first pixel circuit element may be designed according to the particular pixel circuit design, and the first pixel circuit element may be fabricated using processes known in the art. For example, on the surface of the first substrate 100 in the visible-light pixel region may be formed a floating diffusion region and a plurality of MOS transistors (e.g., “MOS”, as shown in FIG. 4A) configured for transmission of signals sensed by the visible-light sensing element PD1. The MOS transistor may include a gate dielectric layer 101 formed on the surface of the first substrate 100, a gate formed on the gate dielectric layer 101, spacers covering side surfaces of the gate, and lightly-doped drain (LDD) and source and drain regions formed in the first substrate 100 lateral to the side surfaces of the gate. Optionally, before, after or during the formation of the MOS transistors on the surface of the first substrate 100, a pinning layer (not shown) may be formed on top of the visible-light sensing element PD1 by heavily doping the first substrate 100 on top of the visible-light sensing element PD1.

FIG. 4B shows a cross-sectional view of the second substrate 200 after second pixel circuit element is formed on the front side thereof. Referring to FIG. 4B, after the infrared light sensing element(s) PD2 is/are formed in the second infrared light pixel region(s) A42 of the second substrate 200, second pixel circuit element may be formed on a surface of the second substrate 200. The structure of the second pixel circuit element may be designed according to particular pixel circuit design. For example, on the surface of the second substrate 200 may be formed a floating diffusion region and a plurality of MOS transistors (e.g., “MOS”, as shown in FIG. 4B) configured for transmission of signals sensed by the infrared light sensing element PD2. The MOS transistor may include a gate dielectric layer 201 formed on the surface of the second substrate 200, a gate formed on the gate dielectric layer 201, spacers covering side surfaces of the gate, and LDD and source and drain regions formed in the second substrate 200 lateral to the side surfaces of the gate. Optionally, before, after or during the formation of the MOS transistors on the surface of the second substrate 200, a pinning layer (not shown) may be formed on top of the infrared light sensing element PD2 by heavily doping the second substrate 200 on top of the infrared light sensing element PD2.

FIG. 5A shows a cross-sectional view of the first substrate 100 after a first dielectric layer 110 and first metal interconnect structure 120 are formed on the front side thereof. Referring to FIG. 5A, after the first pixel circuit element is formed on the surface of the first substrate 100, a first dielectric layer 110 covering the first pixel circuit element and a first metal interconnect structure 120 located in the first dielectric layer 110 and connected to the first pixel circuit element are formed. The first metal interconnect structure 120 may include a metal bond pad flush with a top surface of the first dielectric layer 110.

In one embodiment, as shown in FIG. 5A, during the formation of the first dielectric layer 110 and the first metal interconnect structure 120, a first metal ring MR1 may also be formed in the first dielectric layer 110, the orthographic projection of the first metal ring MR1 on the front side of the first substrate 100 surrounds the first infrared light pixel region A41. For example, during the formation of a through hole and a metal layer for the first metal interconnect structure 120 in the first dielectric layer 110, the through hole and the metal layer may be simultaneously formed around the first infrared light pixel region A41. Moreover, as the formation of the first dielectric layer 110 and the first metal interconnect structure 120 is completed, the formation of the first metal ring MR1 around the first infrared light pixel region A41 may be completed at the same time. As shown in FIG. 5A, the first metal ring MR1 may extend in a heightwise direction thereof through the entire thickness of the first dielectric layer 110, or part thereof. The first metal ring MR1 may be connected to the STI structure STI surrounding the first infrared light pixel region A41. With this arrangement, during transmission of the incident light signal from the first infrared light pixel region A41 into the first dielectric layer 110, it will be blocked by the first metal ring MR1, reducing the risk of straying. At this point, the first pixel substrate 10 has been formed from the first substrate 100, as shown in FIG. 5A.

FIG. 5B shows a cross-sectional view of the second substrate 200 after a second dielectric layer 210 and a second metal interconnect structure 220 are formed on the front side thereof. Referring to FIG. 5B, after the second pixel circuit element is formed on the surface of the second substrate, a second dielectric layer 210 covering the second pixel circuit element and the second metal interconnect structure 220 located in the second dielectric layer 210 and connected to the second pixel circuit element are formed. The second metal interconnect structure 220 may include a metal bond pad flush with a top surface of the second dielectric layer 210.

In one embodiment, as shown in FIG. 5B, during the formation of the second dielectric layer 210 and the second metal interconnect structure 220, a second metal ring MR2 may also be formed in the second dielectric layer 210, an orthographic projection of the second metal ring MR2 on the front side of the second substrate 200 surrounds the second infrared light pixel region A42. For example, during the formation of through hole and metal layer for the second metal interconnect structure 220 in the second dielectric layer 210, the through hole and metal layer may be simultaneously formed around the second infrared light pixel region A42. Moreover, as the formation of the second dielectric layer 210 and the second metal interconnect structure 220 is completed, the formation of the second metal ring MR2 around the second infrared light pixel region A42 may be completed at the same time. As shown in FIG. 5B, the second metal ring MR2 may extend in a heightwise direction thereof through the entire thickness of the second dielectric layer 210, or part thereof. The second metal ring MR2 may be connected to the STI structure STI surrounding the second infrared light pixel region A42. With this arrangement, during transmission of incident light signal into the second dielectric layer 210, they will be blocked by the second metal ring MR2, reducing the risk of straying. At this point, the second pixel substrate 20 has been formed from the second substrate 100, as shown in FIG. 5B.

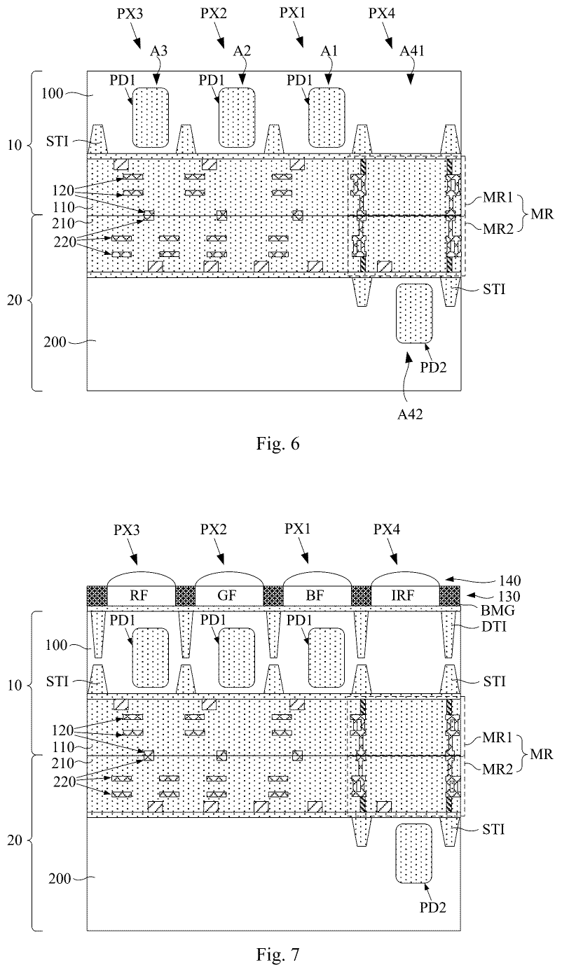

FIG. 6 shows a cross-sectional view of the first pixel substrate 10 and the second pixel substrate 20 after they are bonded together. Referring to FIGS. 1 and 6, after the first pixel substrate 10 and the second pixel substrate 20 are formed as discussed above, in step S2, the first pixel substrate 10 and the second pixel substrate 20 are vertically stacked and bonded together to form a stacked substrate structure.

The first pixel substrate 10 and the second pixel substrate 20 may be held with the first dielectric layer 120 and the second dielectric layer 220 facing each other and then bonded together by hybrid or fusion bonding. The locations of the at least one first infrared light pixel region A41 in the first substrate 100 and the at least one second infrared light pixel region A42 in the second substrate 200 may be appropriately configured so that, as a result of the first pixel substrate 10 and the second pixel substrate 20 being bonded together, each of the at least one first infrared light pixel region A41 in the first pixel substrate 10 is vertically aligned with a corresponding one of the at least one second infrared light pixel region A42 in the second pixel substrate 20 (each pair of the first infrared light pixel region A41 and the second infrared light pixel region A42 is located at the same straight line perpendicular to both the first pixel substrate 10 and the second pixel substrate 20).

In the present embodiment, in the stacked substrate structure formed by bonding the first pixel substrate 10 and the second pixel substrate 20 together, the vertically arranged first and second infrared light pixel regions A41, A42 are laterally distributed and non-overlapping with the visible-light pixel region. Accordingly, the infrared light sensing element PD2 formed in the second infrared light pixel region A42 is laterally distributed and non-overlapping with the visible-light sensing element PD1 in the visible-light pixel region. Thus, laterally distributed different sensing regions, i.e., pixel units, are formed in the stacked substrate structure. Specifically, the stacked substrate structure includes visible-light pixel unit(s) formed in the corresponding visible-light pixel region(s) (e.g., PX1, PX2, PX3, as shown in FIG. 6) and infrared light pixel unit PX4 formed in the first infrared light pixel region A41. Each of the visible-light pixel units and the infrared light pixel unit PX4 extends along the thickness of the stacked substrate structure. The visible-light sensing element PD1 and the infrared light sensing element PD2 are configured to sense visible light and infrared light incident from the side of the first pixel substrate 10 away from the second pixel substrate 20, respectively. That is, the side of the first pixel substrate 10 away from the second pixel substrate 20 is a light incident side, the light radiation incident on the visible-light pixel unit from the light incident side can be sensed by the visible-light sensing element PD1 in the first pixel substrate 10, thereby producing visible light signal. At the same time, the light radiation incident on the infrared light pixel unit PX4 propagates through the first pixel substrate 10, the first dielectric layer 110 and the second dielectric layer 210 into the second pixel substrate 20 and is sensed by the infrared light sensing element PD2. Because of a longer optical path length for the light radiation incident on the infrared light pixel unit PX4, it is less likely for infrared light to transmit through the depletion layer in the infrared light sensing element PD2, making it easier to sense. An overall thickness of the stacked first and second dielectric layers 110, 210 is, for example, about 4 μm to 7 μm.

In the present embodiment, when the first pixel substrate 10 and the second pixel substrate 20 are bonded to each other, the first dielectric layer 110 and the second dielectric layer 210 are boned to each other, simultaneously the first metal interconnect structure 120 and first metal ring MR1 exposed at the top surface of the first dielectric layer 110 are bonded to the second metal interconnect structure 220 and the second metal ring MR2 exposed at the top surface of the second dielectric layer 210, respectively, thereby interconnecting the first pixel substrate 10 and the second pixel substrate 20. By bonding the first and second metal rings MR1, MR2, a metal ring MR is formed between the first substrate 100 and the second substrate 200 around the infrared light pixel unit, and the metal ring MR forms physical isolation around the infrared light pixel unit, effectively avoiding light incident on the infrared light pixel unit PX4 from straying away therefrom during its propagation towards the infrared light sensing element PD2.

As shown in FIG. 6, after the bonding process is completed, the first substrate 100 may be thinned from the backside, allowing subsequent isolation of the visible-light pixel unit and the infrared light pixel unit PX4 at the backside of the first substrate 100 and formation of structures configured for incidence of light thereon. The first substrate 100 may be thinned, for example, to a thickness of 2 μm to 4 μm.

FIG. 7 shows a cross-section view of a structure resulting from forming DTI structures DTI, a light filter layer 130 and a lens layer 140 on the side of the first pixel substrate 10 away from the second pixel substrate 20. Referring to FIG. 7, after the first pixel substrate 10 and the second pixel substrate 20 are bonded, the method may further include the steps as detailed below.

At first, the first substrate 100 is thinned from the backside, and the DTI structure DTI is formed between the at least one visible-light pixel unit and the at least one infrared light pixel unit PX4. The DTI structure DTI may have any desired depth according to requirement. For example, in one embodiment, the DTI structure DTI may extend through the first substrate 100.

Next, a light filter layer 130 is formed on the backside of the first substrate 100. The light filter layer 130 includes a black matrix grid BMG which covers the region between the at least one visible-light pixel unit and the at least one infrared light pixel unit PX4 and comprises openings corresponding to the visible-light pixel unit and the infrared light pixel unit PX4, and filter element filled in the openings. As shown in FIG. 7, for example, a silicon oxide buffer layer and a black matrix material layer may be formed on the backside of the first substrate 100. The black matrix material layer may be a material with low transparency, such as a black or almost black material. Subsequently, the black matrix material layer may be etched, forming openings aligned with the visible-light pixel unit and the infrared light pixel unit PX4. Afterwards, a red filter material is filled in the opening(s) corresponding to one or more of the visible-light pixel units (e.g., PX3), forming red filter element RF. A green filter material is filled in the opening(s) corresponding to another one or more of the visible-light pixel units (e.g., PX2), forming green filter element GF. A blue filter material is filled in the opening(s) corresponding to yet another one or more of the visible-light pixel units (e.g., PX1), forming blue filter element BF. An infrared filter material is filled in the opening corresponding to the infrared light pixel unit PX4, forming infrared filter element IRF. The red filter element RF can filter incident light, allowing component thereof in the red band to reach the visible-light sensing element PD1 in the corresponding visible-light pixel unit. The green filter element GF can filter incident light, allowing component thereof in the green band to reach the visible-light sensing element PD1 in the corresponding visible-light pixel unit. The blue filter element BF can filter incident light, allowing component thereof in the blue band to reach the visible-light sensing element PD1 in the corresponding visible-light pixel unit. The infrared filter element IRF can filter incident light, allowing component thereof in the infrared band to reach the infrared light sensing element PD2 in the corresponding infrared light pixel unit PX4. In an alternative embodiment, the opening corresponding to the infrared light pixel unit PX4 may be filled with transparent material without filtering the infrared light.

Subsequently, a lens layer 140 is formed on a side of the light filter layer 130 away from the first substrate 100. The lens layer 140 includes micro-lenses corresponding to the at least one visible-light pixel unit and the at least one infrared light pixel unit PX4.

In the method for fabricating the CIS device described in the above embodiment, the first pixel substrate 10 and the second pixel substrate 20 are separately formed and then bonded together, and the resulting stacked substrate structure includes the visible-light pixel unit formed in the visible-light pixel region and the infrared light pixel unit PX4 formed in the first infrared light pixel region A41 (or in the second infrared light pixel region A42). These pixel units are laterally offset from each other or one another, without any overlap therebetween. Thus, they can separately form images without sharing a common optical path, avoiding possible mutual interference between optical paths. Compared with the visible-light pixel unit, the incident light corresponding to the infrared light pixel unit PX4 travels a longer distance before it is detected, resulting in enhanced response to the infrared light. In addition, the incident light corresponding to the visible-light pixel unit travels a shorter distance before it is detected due to a smaller depth of depletion layer, reducing the risk of crosstalk between adjacent pixel units. Further, since the infrared light has a longer wavelength than visible light, the STI and DTI structures STI, DTI are less effective in isolating crosstalk of infrared light than in isolating crosstalk of visible light. Accordingly, the metal ring MR is formed around the infrared light pixel unit PX4 between the first substrate 100 and the second substrate 200 to enhance the isolation of crosstalk of infrared light.

In some embodiments, after the first pixel substrate 10 and the second pixel substrate 20 are bonded together, the second substrate 200 may also be thinned from the backside (e.g., to a thickness of 2 μm to 4 μm), and one, two or more substrates, for example, configured for data storage or processing, may be bonded to the side of the second pixel substrate 20 facing away from the first pixel substrate 10.

In the method for fabricating the CIS device described in the above embodiment, the first pixel substrate 10 may be formed as a backside-illustrated (BSI) substrate and the second pixel substrate 20 as a front side-illustrated (FSI) substrate, and the two may be bonded to form electrically interconnection. However, the present invention is not so limited. In some other embodiments, the first pixel substrate 10 and the second pixel substrate 20 may be formed both as BSI or FSI substrates, or the first pixel substrate 10 may be formed as an FSI substrate and the second pixel substrate 20 as a BSI substrate. Through laterally integrating the visible-light pixel unit that has a shorter optical path for incident light with the infrared light pixel unit PX4 that has a longer optical path for incident light, the resulting CIS device shows enhanced response to infrared radiation, without the risk of increased crosstalk between adjacent pixel units.

Embodiments of the present invention are also directed to a CIS device obtainable according to the method discussed above, or according to other suitable methods. Referring to FIGS. 1 to 7, the CIS device includes a stacked substrate structure including: a first pixel substrate 10 and a second pixel substrate 20, which are vertically bonded to each other; and at least one visible-light pixel unit (e.g., PX1 to PX3 of FIG. 7) and at least one infrared light pixel unit PX4 which do not laterally overlap. The visible-light pixel unit includes a visible-light sensing element PD1 formed in the first pixel substrate 10, and the infrared light pixel unit PX4 includes an infrared light sensing element PD2 formed in the second pixel substrate 20. The visible-light sensing element PD1 and the infrared light sensing element PD2 are configured to sense visible and infrared light incident on a side of the first pixel substrate 10 away from the second pixel substrate 20, respectively.

As shown in FIG. 7, the first pixel substrate 10 includes a first substrate 100 and a first dielectric layer 110 formed on a side thereof facing the second pixel substrate 20. The visible-light sensing element PD1 of the visible-light pixel unit is formed in the first substrate 100. The second pixel substrate 20 includes a second substrate 200 and a second dielectric layer 210 formed on a side thereof facing the first pixel substrate 10. The first dielectric layer 110 and the second dielectric layer 210 are adjacent to and bonded to each other. The infrared light sensing element PD2 of the infrared light pixel unit PX4 is formed in the second substrate 200. Optionally, trench isolation structure (STI structure STI and/or DTI structure DTI) is formed in the first substrate 100, the at least one visible-light pixel unit and the at least one infrared light pixel unit PX4 are isolated by the trench isolation structure.

For example, the first pixel substrate 10 may be a BSI substrate, wherein the side of the first pixel substrate 10 away from second pixel substrate 20 (which is a light incident side) is a backside of the first substrate 100, and the first dielectric layer 110 is formed on a front side of the first substrate 100. The first pixel substrate 10 may also include a first metal interconnect structure 120 formed in the first dielectric layer 110. However, the present invention is not so limited. In another embodiment, the first pixel substrate 100 may be an FSI substrate, wherein the light incident side is the front side of the first substrate 100, and the first dielectric layer 110 is formed on the backside of the first substrate 100.

As shown in FIG. 7, for example, the second pixel substrate 20 may be an FSI substrate, wherein the light incident side is a front side of the second substrate 200, and the second dielectric layer 210 is formed on the front side of the second substrate 100. The second pixel substrate 20 may further include a second metal interconnect structure 220 formed in the second dielectric layer 210. However, the present invention is not so limited. In another embodiment, the second pixel substrate 20 may be a BSI substrate, wherein the light incident side is the backside of the second substrate 200, and the second dielectric layer 210 is formed on the backside of the second substrate 100.

Referring to FIG. 7, the first metal interconnect structure 120 may include a metal bond pad on a top surface of the first dielectric layer 110, and the second metal interconnect structure 220 may include a metal bond pad on a top surface of the second dielectric layer 210. For example, the first pixel substrate 10 and the second pixel substrate 20 may be bonded together by hybrid bonding, and the metal bond pad on the top surface of the first dielectric layer 110 is bonded to the metal bond pad on the top surface of the second dielectric layer 120 at a bonding interface between the first dielectric layer 110 and second dielectric layer 120, thereby interconnecting the first metal interconnect structure 120 and the second metal interconnect structure 220. In an alternative embodiment, the first metal interconnect structure 120 and the second metal interconnect structure 220 may be interconnected not by bonding.

As shown in FIG. 7, the first pixel substrate 10 may optionally include a first metal ring MR1 formed in the first dielectric layer 110, an orthographic projection of which on the front side of the first substrate 100 surrounds the infrared light pixel unit PX4. That is, the infrared light pixel unit PX4 is isolated by the first metal ring MR1 in the first dielectric layer 110. For example, STI structure STI may be formed at the front side of the first substrate 100 to isolate the pixel units. For example, the first metal ring MR1 may be connected to the STI structure STI that isolates the infrared light pixel unit PX4 and extend along the thickness of the first dielectric layer 110. The First metal ring MR1 may extend through the entire thickness of the first dielectric layer 110, or part thereof. The first metal ring MR1 helps increase isolation of crosstalk of infrared light.

As shown in FIG. 7, the second pixel substrate 20 may optionally include a second metal ring MR2 formed in the second dielectric layer 210, an orthographic projection of which on the front side of the first substrate 100 also surrounds the infrared light pixel unit PX4. That is, the infrared light pixel unit PX4 is isolated by the second metal ring MR2 in the second dielectric layer 210. For example, STI structure STI may be formed at the front side of the second substrate 200 to isolate the infrared light pixel unit PX4. For example, the second metal ring MR2 may be connected to the STI structure STI that isolate the infrared light pixel unit PX4 and extend along the thickness of the second dielectric layer 210. The second metal ring MR2 may extend through the entire thickness of the second dielectric layer 210, or part thereof.

In some embodiments, when the infrared light pixel unit PX4 is isolated by the first metal ring MR1 in the first dielectric layer 110 and by the second metal ring MR2 in the second dielectric layer 210, the first metal ring MR1 and the second metal ring MR2 both around the infrared light pixel unit PX4 may be bonded to each other at the bonding interface between the first dielectric layer 110 and the second dielectric layer 210, forming a metal ring MR, which can enhance isolation of crosstalk of infrared light.

As shown in FIG. 7, the first pixel substrate 10 may include DTI structure DTI, a light filter layer 130 and a lens layer 140, all formed on the backside of the first substrate 100. The DTI structure DTI is formed between the at least one visible-light pixel unit and the at least one infrared light pixel unit PX4. The light filter layer 130 includes a black matrix grid BMG which covers a region between the at least one visible-light pixel unit and the at least one infrared light pixel unit PX4 and comprises openings corresponding to the visible-light pixel unit and the infrared light pixel unit PX4, and filter elements filled in the openings. The lens layer 140 is formed on a side of the light filter layer 130 away from the first pixel substrate 10 and includes micro-lenses corresponding to the at least one visible-light pixel unit and the at least one infrared light pixel unit PX4.

In the above described CIS device, the at least one visible-light pixel unit and at least one infrared light pixel unit PX4 do not laterally overlap, and the visible-light pixel unit comprises the visible-light sensing element PD1 formed in the first pixel substrate 10, and the infrared light pixel unit PX4 comprises the infrared light sensing element PD2 formed in the second pixel substrate 20, the visible-light sensing element PD1 and the infrared light sensing element PD2 are configured to sense visible light and infrared light incident on the side of the first pixel substrate 10 away from the second pixel substrate 20, respectively. Compared with the visible-light pixel unit, the incident light corresponding to the infrared light pixel unit PX4 travels a longer distance before it is detected, resulting in enhanced response to infrared light. In addition, incident light corresponding to the visible-light pixel unit travels a shorter distance before it is detected due to a smaller depth of a depletion layer, reducing the risk of crosstalk between adjacent pixel units. Further, the metal ring MR formed around the infrared light pixel unit PX4 that disposed between the first substrate 100 and the second substrate 200 can enhance isolation of crosstalk of infrared light.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A CMOS image sensor (CIS) device, comprising a stacked substrate structure, wherein the stacked substrate structure comprises: a first pixel substrate and a second pixel substrate that are vertically bonded to each other; and at least one visible-light pixel unit and at least one infrared light pixel unit that do not laterally overlap, wherein the visible-light pixel unit comprises a visible-light sensing element formed in the first pixel substrate, wherein the infrared light pixel unit comprises an infrared light sensing element formed in the second pixel substrate, wherein the visible-light sensing element and the infrared light sensing element are configured to sense visible light and infrared light incident on a side of the first pixel substrate away from the second pixel substrate, respectively.

2. The CIS device of claim 1, wherein the first pixel substrate comprises a first substrate and a first dielectric layer formed on a side of the first substrate facing the second pixel substrate, and wherein the second pixel substrate comprises a second substrate and a second dielectric layer formed on a side of the second substrate facing the first pixel substrate, wherein the second dielectric layer is adjacent to and bonded to the first dielectric layer.

3. The CIS device of claim 2, wherein a trench isolation structure is formed in the first substrate, and wherein the at least one visible-light pixel unit and the at least one infrared light pixel unit are isolated in the first substrate by the trench isolation structure.

4. The CIS device of claim 2, wherein a first metal ring is formed in the first dielectric layer, and the infrared light pixel unit is isolated in the first dielectric layer by the first metal ring, and/or wherein a second metal ring is formed in the second dielectric layer, and the infrared light pixel unit is isolated in the second dielectric layer by the second metal ring.

5. The CIS device of claim 4, wherein when a same infrared light pixel unit is isolated in the first dielectric layer by the first metal ring and in the second dielectric layer by the second metal ring, the first and second metal rings are bonded to each other at a bonding interface between the first and second dielectric layers.

6. The CIS device of claim 2, wherein the first pixel substrate is a backside-illustrated substrate, with the first dielectric layer being formed on a front side of the first substrate, wherein the first pixel substrate further comprises a first metal interconnect structure formed in the first dielectric layer, wherein the second pixel substrate is a front side-illustrated substrate, with the second dielectric layer being formed on a front side of the second substrate, wherein the second pixel substrate further comprises a second metal interconnect structure formed in the second dielectric layer, and wherein the first and second metal interconnect structures are bonded to each other at a bonding interface between the first and second dielectric layers.

7. The CIS device of claim 1, further comprising:
a light filter layer formed on the side of the first pixel substrate away from the second pixel substrate, wherein the light filter layer comprises: a black matrix grid that covers a region between the at least one visible-light pixel unit and the at least one infrared light pixel unit and comprises openings corresponding to the visible-light pixel unit and the infrared light pixel unit; and filter elements filled in the openings; and
a lens layer formed on a side of the light filter layer away from the first pixel substrate, wherein the lens layer comprises micro-lenses corresponding to the at least one visible-light pixel unit and the at least one infrared light pixel unit.

8. A method for fabricating a CMOS image sensor (CIS) device, comprising:
forming a first pixel substrate and a second pixel substrate, wherein the first pixel substrate comprises at least one visible-light pixel region and at least one first infrared light pixel region that do not laterally overlap, wherein the visible-light pixel region is provided with a visible-light sensing element, wherein the second pixel substrate comprises at least one second infrared light pixel region that does not laterally overlap, and wherein the second infrared light pixel region is provided with an infrared light sensing element; and
vertically stacking and bonding the first and second pixel substrates to form a stacked substrate structure, wherein each of the at least one first infrared light pixel region in the first pixel substrate is vertically aligned with a corresponding one of the at least one second infrared light pixel region in the second pixel substrate, wherein the stacked substrate structure comprises a visible-light pixel unit corresponding to the visible-light pixel region and an infrared light pixel unit corresponding to the first infrared light pixel region, and wherein the visible-light sensing element and the infrared light sensing element are configured to respectively sense visible light and infrared light incident on a side of the first pixel substrate away from the second pixel substrate.

9. The method of claim 8, wherein forming the first pixel substrate comprises:
forming a shallow trench isolation (STI) structure at a front side of a first substrate to define the at least one visible-light pixel region and the at least one first infrared light pixel region;
forming the visible-light sensing element in the at least one visible-light pixel region; and
forming, on the front side of the first substrate, a first pixel circuit element that is coupled to the visible-light sensing element, a first dielectric layer that covers the first pixel circuit element and a first metal interconnect structure that is formed in the first dielectric layer and is connected to the first pixel circuit element.

10. The method of claim 9, wherein during the formation of the first dielectric layer and the first metal interconnect structure, a first metal ring is formed in the first dielectric layer, wherein an orthographic projection of the first metal ring on the front side of the first substrate surrounds the first infrared light pixel region.

11. The method of claim 9, wherein forming the second pixel substrate comprises:
forming a STI structure at a front side of a second substrate to define the at least one second infrared light pixel region;
forming the infrared light sensing element in the at least one second infrared light pixel region; and
forming, on the front side of the second substrate, a second pixel circuit element that is coupled to the infrared light sensing element, a second dielectric layer that covers the second pixel circuit element and a second metal interconnect structure that is formed in the second dielectric layer and is connected to the second pixel circuit element, and
wherein the first and second dielectric layers are bonded by bonding the first and second pixel substrates, and wherein the first and second metal interconnect structures are bonded at a bonding interface between the first and second dielectric layers.

12. The method of claim 11, wherein during the formation of the second dielectric layer and the second metal interconnect structure, a second metal ring is formed in the second dielectric layer, and wherein an orthographic projection of the second metal ring on the front side of the second substrate surrounds the second infrared light pixel region.

13. The method of claim 9, further comprising, after the first and second pixel substrates are bonded:
thinning the first substrate from a backside thereof and forming a deep trench isolation structure between the at least one visible-light pixel unit and the at least one infrared light pixel unit; and
sequentially forming a light filter layer and a lens layer on the backside of the first substrate.
